(19) United States
(12) Patent Application Publication
(10) Pub. No.: US 2022/0046827 A1
(43) Pub. Date: Feb. 10, 2022

(54) Server

(71) Applicant: Beijing Silicon Based Voyage Technology Co., Ltd., Beijing (CN)

(72) Inventor: Bin YANG, Beijing (CN)

(73) Assignee: Beijing Silicon Based Voyage Technology Co., Ltd., Beijing (CN)

(21) Appl. No.: 17/398,019

(22) Filed: Aug. 10, 2021

(30) Foreign Application Priority Data
Aug. 10, 2020 (CN) 202021651216.1

(51) Int. Cl. H05K 7/20; H05K 7/14

(52) U.S. Cl. CPC H05K 7/20809; H05K 7/20772; H05K 7/1492

(57) ABSTRACT

The disclosure provides a server including a housing in the shape of a frame structure, a plurality of Hash boards disposed side by side in the housing along a first direction, and a cooling module configured to cool at least the plurality of Hash boards; each of the plurality of Hash boards are disposed perpendicularly to the first direction, and each Hash board includes a board body provided with a Hash chip; the cooling module includes at least one first cooling plate disposed on the board body, a water-cooling plate disposed on a side surface of the board body, and at least one heat pipe disposed on the board body; one end of the at least one heat pipe is disposed on the at least one first cooling plate, and the other end is disposed on the water-cooling plate.

### FIELD OF THE INVENTION

The disclosure relates to the field of servers, and particularly to a server.

### BACKGROUND

With the rapid development of electronic information technology, servers are increasingly used in various fields. In operation, the serves consume a lot of energy and produce much heat. How to cool the server has become a particularly important problem facing the technicians in the art.

In related art, the servers are equipped with a plurality of parallel Hash boards, and some servers employ system fans for heat dissipation, which will consume much energy and make a lot of noise. The system fans are generally disposed at one end of a plurality of Hash boards. Owing to the shielding of the board body, the heat at both ends of the Hash boards cannot be dissipated. Optionally, each Hash board of certain servers is provided with an independent cooling fan and other radiators, and the cooling fan is disposed between two adjacent Hash boards. The arrangement of the plurality of cooling fans tends to reduce the size of a single cooling fan and increase the failure rate thereof, thus increasing the difficulty of heat dissipation, and the cold and hot air path is not clear, leading to the difficulty of the heat dissipation of the hot reflux. In addition, owing to the limited spacing between the plurality of Hash boards, the thickness of the cooling fan is limited, which limits the heat dissipation capacity thereof.

### SUMMARY

To solve the problems in the related art, one objective of the disclosure is to provide a server with good heat dissipation effect.

According to one embodiment of the disclosure, the server comprises:

a housing in the shape of a frame structure;

a plurality of Hash boards disposed side by side in the housing along a first direction; each of the plurality of Hash boards being disposed perpendicularly to the first direction, and each Hash board comprising a board body; the board body being provided with a Hash chip; and

a cooling module configured to cool at least the plurality of Hash boards;

the cooling module comprising:
at least one first cooling plate disposed on the board body;
a water-cooling plate disposed on a side surface of the board body, and
at least one heat pipe disposed on the board body; one end of the at least one heat pipe being disposed on the at least one first cooling plate, and the other end being disposed on the water-cooling plate.

With regard to the server of the disclosure, the heat pipe is disposed on the board body; one end of the heat pipe is disposed on the first cooling plate, and the other end is disposed on the water-cooling plate, so that a heat transfer channel is established, and a conventional cooling fan is not necessarily disposed, thereby reducing the energy consumption, saving the cost, and no noise is produced when the server is running, with good heat dissipation effect and thermal stability, and achieving long-distance heat dissipation. At the same time, the utilization efficiency of the water-cooling plate is increased, which further improves the heat dissipation efficiency of the heat source. In addition, the problems of heat source cascade and hot air backflow on the plurality of Hash boards are avoided, thus facilitating the diversified design of the heat source. And, the cooperation of the first cooling plate, the water-cooling plate and the heat pipe of the cooling module can further improve the heat dissipation effect.

In certain embodiments, the Hash board comprises a buck circuit module disposed on the board body and separated from the Hash chip in a second direction which is parallel to an extension direction of the Hash board; and the first cooling plate is disposed on the buck circuit module.

In certain embodiments, a plurality of first cooling plates are disposed at intervals on the buck circuit module, and each first cooling plate corresponds to at least one heat pipe.

In certain embodiments, the cooling module comprises one first cooling plate, and one end of each heat pipe is disposed on the one first cooling plate.

In certain embodiments, the server further comprises a second cooling plate disposed on a side surface of the water-cooling plate away from the board body, and one end of each heat pipe away from the first cooling plate is disposed on the second cooling plate.

In certain embodiments, at least one of the first cooling plate and the second cooling plate comprise at least one elongated groove configured to accommodate a part of the heat pipe.

In certain embodiments, a heat conducting gel configured to adjust a height of the first cooling plate is provided between the buck circuit module and the first cooling plate.

In certain embodiments, each heat pipe comprises: a first section disposed on one end of the water-cooling plate; a second section disposed on one end of the first cooling plate, and a distance between the second section and the board body being less than a distance between the first section and the board body; and a connection section disposed between the first section and the second section and presenting in a step structure.

In certain embodiments, the relationship of a height h and a horizontal length L of the connection section is as follows: 1/20≤h/L≤½.

In certain embodiments, the first section and the connection section, and the second section and the connection section are connected through arcs, and a radius of the arcs is greater than or equal to twice a diameter of the heat pipe.

Other aspects and advantages of the disclosure will be partially given in the following description, and will be easy to understand through the following description or be learned from the practice of the disclosure.

### BRIEF DESCRIPTION OF THE DRAWINGS

The above and/or additional aspects and advantages of the disclosure will become obvious and easy to understand from the description of the embodiment in combination with the following drawings:

FIG. 1 is a schematic view of a server according to one embodiment of the disclosure;

FIG. 2 is a schematic view of a Hash board of a server according to one embodiment of the disclosure in a first angle of view;

FIG. 3 is a sectional view taken from line A-A in FIG. 2;

FIG. 4 is a sectional view taken from line B-B in FIG. 2;

FIG. 5 is a schematic view of a Hash board of a server according to one embodiment of the disclosure in a second angle of view;

FIG. 6 is an enlarged view of part C in FIG. 5;

FIG. 7 is a schematic view of a Hash board of a server according to one embodiment of the disclosure in a third angle of view;

FIG. 8 is an enlarged view of part D in FIG. 7; and

FIG. 9 is a schematic view of a Hash board of a server according to one embodiment of the disclosure in a fourth angle of view.

### NUMERALS IN THE FIGURES

100. Server;
10. Housing;
20. Hash board; 21. Board body; 211. Hash chip; 22. Buck circuit module;
30. Cooling module; 41. First cooling plate; 42. Water-cooling plate; 43. Heat pipe; 431. First section; 432. Second section; 433. Connection section;
40. Second cooling plate; 50. Elongated groove; 60. Baffle plate; 70. Handle; 80. Power module.

### DETAILED DESCRIPTION

The embodiments of the disclosure are described in detail below with reference to the attached exemplary drawings.

In the description of the disclosure, it should be understood that the orientation or position relationship indicated by the terms “thickness”, “horizontal”, “up”, “down”, “bottom”, “front”, “back”, “left”, “right”, “inside” and “outside” is based on the orientation or position relationship shown in the figure, only for the convenience of describing the disclosure and simplifying the description, not to indicate or imply that the device or element must have a specific orientation, be constructed and operated in a specific orientation, and it cannot be understood as a limitation to the disclosure.

In the description of the disclosure, “plurality” means two or more.

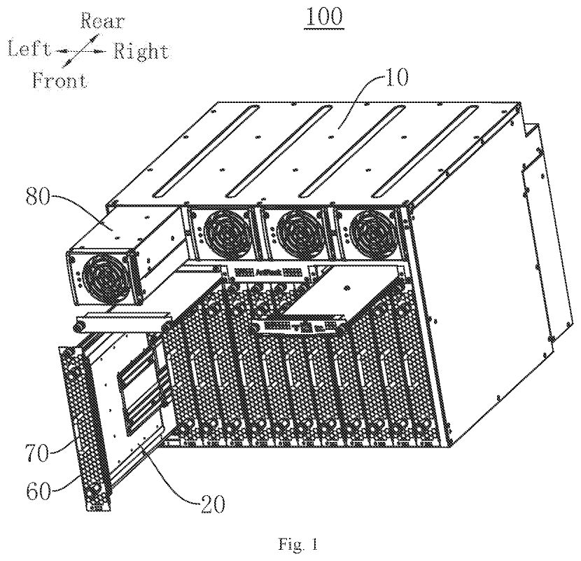

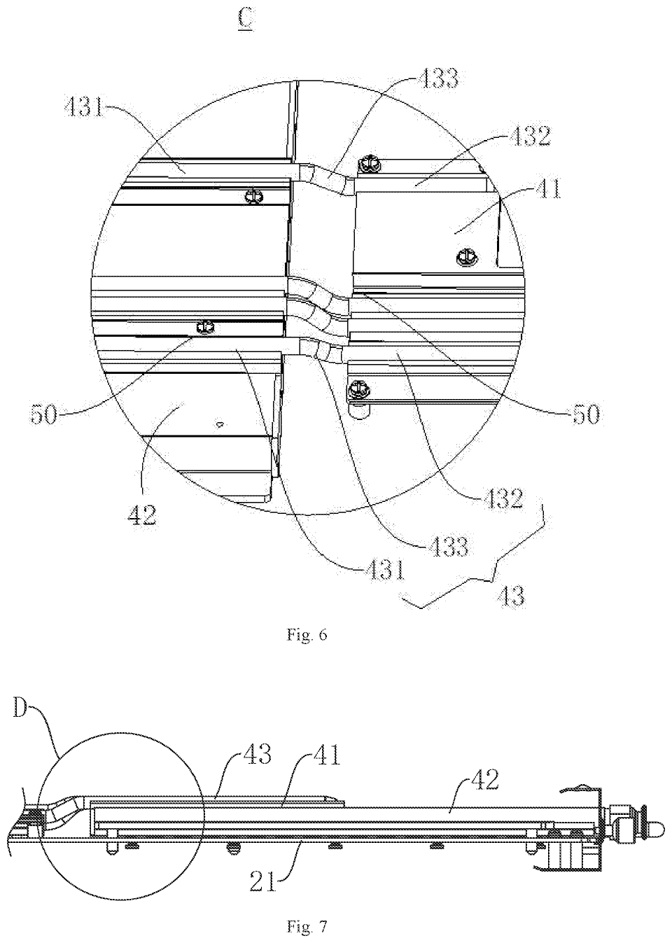

As shown in FIGS. 1-9, a server 100 of the disclosure comprises a housing 10, a plurality of Hash boards 20, and a cooling module 30.

As shown in FIGS. 1-8, the housing 10 is of a frame structure. The plurality of Hash boards 20 are disposed side by side in the housing 10 along a first direction (for example, from left to right in FIG. 1). Each Hash board is disposed perpendicularly to the first direction, and each Hash board comprises a board body 21. The board body 21 is provided with a Hash chip 211, and the cooling module 30 is configured to cool at least the plurality of Hash boards 20.

The cooling module 30 comprises at least one first cooling plate 41, a water-cooling plate 42, and at least one heat pipe 43. It should be noted that the medium in the pipeline of “water-cooling plate 42” does not necessarily refer to water, but can be a variety of liquids. The heat pipe 43 is a kind of heat transfer element with high thermal conductivity, and can transfer heat through evaporation and condensation of liquid in the pipe. When one end of the heat pipe 43 is heated, the liquid at this end is vaporized, and the produced steam will move from the heated end to the other end. The temperature of the other end is low, where the steam will be liquefied. The condensed liquid can return to the heated end under the action of certain force, for example, capillary force. In such a reciprocating cycle, the liquid in the heat pipe 43 will be continuously vaporized and liquefied. In the vaporization and liquefaction process, the liquid absorbs and releases a lot of heat. Thus, there is a temperature difference between the two ends of the heat pipe 43, so the heat can be transferred quickly, thus achieving the refrigeration effect.

The first cooling plate 41 is disposed on the board body 21. The water-cooling plate 42 is disposed on the side surface of the board body 21. The heat pipe 43 is disposed on the board body 21; one end of the heat pipe 43 is disposed on the first cooling plate 41, and the other end is disposed on the water-cooling plate 42, thereby cooling the to-be cooled position. For example, the first cooling plate 41 is disposed in a heat source; one end of the heat pipe 43 is disposed on the first cooling plate 41, and the other end is disposed on the water-cooling plate 42. In this way, there is a temperature difference between the two ends of the heat pipe 43; the heat source can be cooled through the heat pipe 43, with good heat dissipation effect.

Likewise, the water-cooling plate 42 and the first cooling plate 41 can also play the role of heat dissipation. The heat source can transfer the heat to the first cooling plate 41; the first cooling plate 41 can dissipate the heat, and the first cooling plate 41 can transfer the heat to the heat pipe 43, thus realizing the coordinated heat dissipation of the cooling module 30 and improving the heat dissipation effect. In addition, because the water-cooling plate 42 has a certain thickness, owing to the arrangement of the first cooling plate 41, it is convenient to control the height difference between the two ends of the heat pipe 43, thus facilitating the arrangement of the heat pipe 43. Furthermore, one end of the heat pipe 43 is disposed on the first cooling plate 41, which can have a large contact area with the heat source, thus improving the contact area between the cooling module 30 and the heat source, and improving the heat transfer efficiency and effect, and the heat source can be cooled more effectively.

With regard to the server 100 of the disclosure, the heat pipe 43 is disposed on the board body 21; one end of the heat pipe 43 is disposed on the first cooling plate 41, and the other end is disposed on the water-cooling plate 42, so that a heat transfer channel is established, and a conventional cooling fan is not necessarily disposed, thereby reducing the energy consumption, saving the cost, and no noise is produced when the server 100 is running, with good heat dissipation effect and thermal stability, and achieving long-distance heat dissipation. At the same time, the utilization efficiency of the water-cooling plate 42 is increased, which further improves the heat dissipation efficiency of the heat source. In addition, the problems of heat source cascade and hot air backflow on the plurality of Hash boards 20 are avoided, thus facilitating the diversified design of the heat source. And, the cooperation of the first cooling plate 41, the water-cooling plate 42, and the heat pipe 43 of the cooling module 30 can further improve the heat dissipation effect.

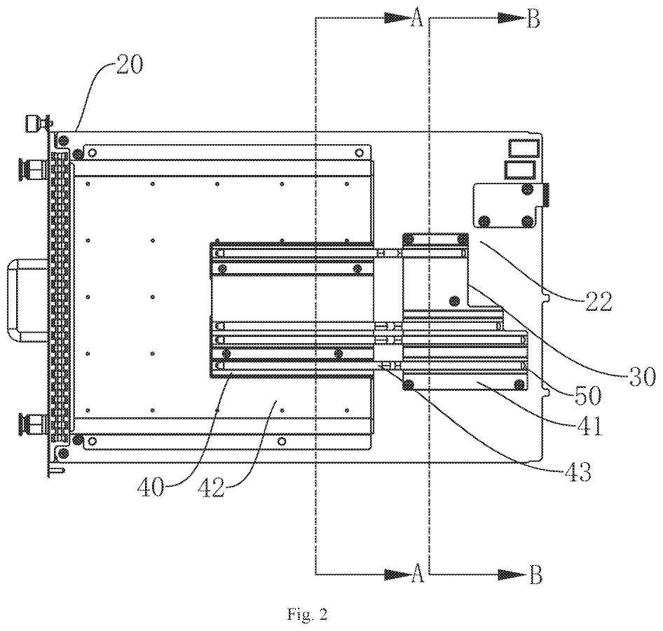

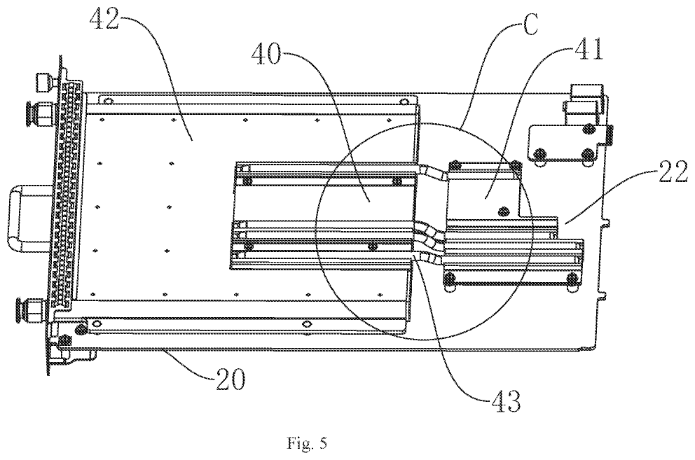

In certain embodiments, with reference to FIGS. 2 and 5, the Hash board 20 further comprises a buck circuit module 22. The buck circuit module 22 is electrically connected to a power module 80 of the server 100 to step down the voltage and supplies the voltage to the Hash chip 211. The buck circuit module 22 is disposed on the board body 21 and separated from the Hash chip 211 in a second direction (for example, from front to rear in FIG. 1), and the second direction is parallel to the extension direction of the Hash board 20. The first cooling plate 41 is disposed on the buck circuit module 22, which achieves the effective cooling of the buck circuit module 22. Optionally, the buck circuit module 22 comprises an inductor module and a Metal Oxide Semiconductor transistors (MOS transistors), and the heat pipe 43 can effectively cool the inductor module and the MOS transistors, thus avoiding the overheating of the inductor module and the MOS transistors, and ensuring the stability of the buck circuit module 22. In other embodiment, the heat source can be other structures needing to be cooled, such as power supply and circuit board. The water-cooling plate 42 of the disclosure can not only cool the Hash chip 211 on the board body 21, but also cool the buck circuit module 22 on the board body 21, so that the heat dissipation capacity of the water-cooling plate 42 is fully utilized, no need to design a fan.

In certain embodiments, a plurality of first cooling plates 41 are disposed at intervals on the buck circuit module 22, and each first cooling plate 41 is connected to at least one heat pipe 43. In other embodiments, only one first cooling plate 41 is disposed on the buck circuit module 22, and one end of each heat pipe 43 is disposed on the one first cooling plate 41. The layout design of the buck circuit module 22 can be in various forms, for example, the buck circuit module 22 is dispersedly arranged in the vicinity of each power module, or the buck circuit module 22 is concentratedly arranged on the board body 21, and the cooling module 30 intensively cools the buck circuit module 22, etc. The cooling module 30 can be designed correspondingly according to the design of the buck circuit module 22 so as to improve the heat dissipation effect.

For example, the heat pipe 43 can be a copper tube or an aluminum alloy tube, so that the heat pipe 43 has good structural strength, can effectively dissipate heat, and has good bending property, so as to facilitate the heat pipe 43 to cooperate with the buck circuit module 22 and the water-cooling plate 42 to form a variety of shapes.

In certain embodiments, for example, as shown in FIGS. 2, 5, and 6, the server 100 further comprises a second cooling plate 40 disposed on the surface of the water-cooling plate 42 away from the board body 21, the end of each heat pipe 43 away from the first cooling plate 41 is disposed on the second cooling plate 40. In this way, all the heat pipes 43 are connected to the first cooling plate 41 and the second cooling plate 40, thus improving the heat dissipation efficiency and effect of the server 100.

For example, the first cooling plate 41 and the second cooling plate 40 can both be aluminum alloy plates, and the aluminum alloy plates have good thermal conductivity and high hardness, so that the first cooling plate 41 and the second cooling plate 40 have good heat dissipation performance and structural strength, thus ensuring the heat dissipation effect. Optionally, the first cooling plate 41 and the second cooling plate 40 can also be made of a variety of materials with good thermal conductivity, such as copper or copper alloy.

In certain embodiments, with reference to FIGS. 2-4 and 6, at least one of the first cooling plate 41 and the second cooling plate 40 comprise at least one elongated groove 50 configured to accommodate a part of the heat pipe 43. The heat pipe 43 can be attached to a plurality of side walls of the elongated groove 50, which, on the one hand, facilitates the installation of the heat pipe 43 and ensures the stability of the heat pipe 43 on the two cooling plates, on the other hand, improves the contact area between the heat pipe 43 and the two cooling plates, so that the server 100 has more excellent heat dissipation efficiency and heat dissipation effect. For example, the first cooling plate 41 and the second cooling plate 40 are both provided with a plurality of elongated grooves 50, and the elongated grooves 50 disposed on the first cooling plate 41 and on the second cooling plate 40 have the same groove width and are disposed correspondingly to each other, thus facilitating the installation of the heat pipe 43.

In another embodiments, with reference to FIGS. 2, 6 and 8, each heat pipe 43 comprises a first section 431 disposed on one end of the water-cooling plate 42, a second section 432 disposed on one end of the first cooling plate 41, and a connection section 433. The distance between the second section 432 and the board body 21 is less than the distance between the first section 431 and the board body 21. The connection section 433 is disposed between the first section 431 and the second section 432 and presents in a step structure. Because the first section 431 is disposed on the water-cooling plate 42, the second section 432 is disposed on the buck circuit module 22, there is a height difference between the first section 431 and the second section 432; the arrangement of the connection section 433 can moderate the height difference, thus ensuring the effective fit of the second section 432 and the buck circuit module 22, and improving the heat dissipation effect. In addition, the connection section 433 disposed in this way can also facilitate the liquid in the first section 431 to move towards the second section 432.

In certain embodiments, a heat conducting gel configured to adjust the height of the first cooling plate 41 is provided between the buck circuit module 22 and the first cooling plate 41. For example, the heat pipe 43 may be installed in the elongated grooves 50 of the two cooling plates by solder paste, welding, or interference fit. After the heat pipe 43 and the two cooling plates are installed into an integrated structure, the second cooling plate 40 of the integrated structure can be fixed on the water-cooling plate 42 through screws. When the first cooling plate 41 is installed on the buck circuit module 22, there will be a certain height difference between the components of the first cooling plate 41 and the buck circuit module 22 owing to manufacturing. The loose connection between the first cooling plate 41 and the buck circuit module 22 adversely affects the heat dissipation efficiency. The heat pipe 43 of the disclosure comprises the connection section 433. When the second cooling plate 40 is disposed on the water-cooling plate 42, the first cooling plate 41 can be attached to the buck circuit module 22 through the deformation of the connection section 433. The deformation can reach millimeter level, for example, to adjust the height difference of 1-5 mm. After the deformation adjustment of the heat pipe 43, there may be a height difference of few tenths of a millimeter between the buck circuit module 22 and the first cooling plate 41, and the heat conduction gel disposed between the buck circuit module 22 and the first cooling plate 41 can further balance the height difference.

The heat conduction gel is deformable under the action of force, so that the height of the first cooling plate 41 can be adjusted by extruding the heat conduction gel thus achieving the floating arrangement of the first cooling plate 41 with respect to the buck circuit module 22, so that the heat conduction gel can balance the tiny tolerance of less than 1 mm, which is conducive to the proper contact between the first cooling plate 41 and the buck circuit module 22, thus achieving the purpose of heat dissipation. Optionally, in other embodiments, a thermal pad is disposed between the buck circuit module 22 and the first cooling plate 41.

In one embodiment, the relationship of the height h and the horizontal length L of the connection section 433 is as follows: 1/20≤h/L≤½. Thus, the height difference between the first section 431 and the second section 432 is ensured, and after being stressed, the connection section 433 is deformable, thus ensuring the installation of the first cooling plate 41 on the buck circuit module 22.

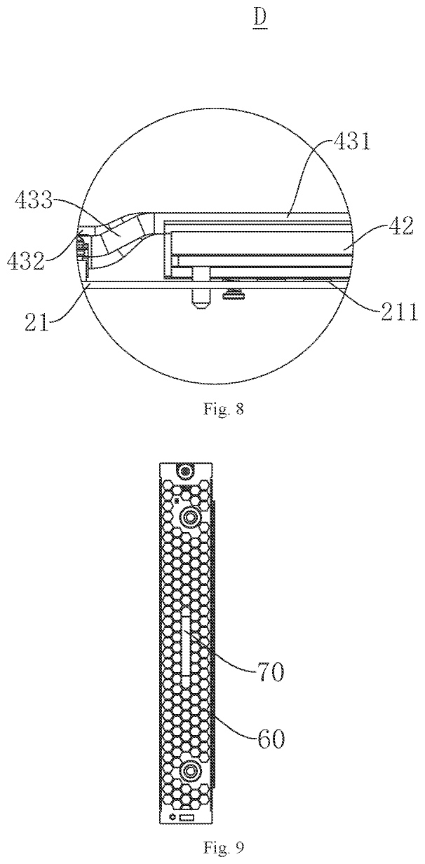

In certain embodiments, as shown in FIG. 8, the first section 431 and the connection section 433, and the second section 432 and the connection section 433 are connected through arcs, and a radius of the arcs is greater than or equal to twice a diameter of the heat pipe 43, thus further improving the structural reliability of the heat pipe 43.

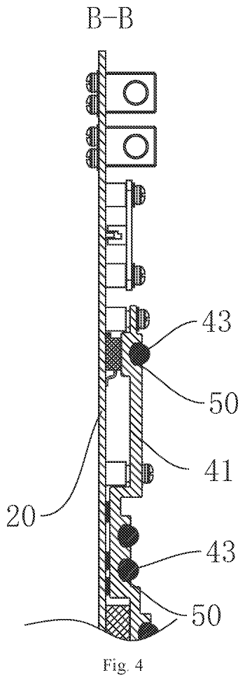

As shown in FIGS. 4 and 8, the plurality of heat pipes 43 can be adjusted according to the structural shape of the heat source. In the side-by-side direction of the plurality of heat pipes 43, the first cooling plates 41 can be disposed at different heights, which can make the second sections 432 of the plurality of heat pipes 43 have different heights to attach to the heat source more closely, to improve the heat dissipation efficiency and heat dissipation effect.

It should be noted that the greater the temperature difference between the two ends of the heat pipe 43, the more conducive to the rapid conduction of heat at both ends, which is conducive to improving the heat dissipation efficiency and heat dissipation effect of the heat pipe 43. The internal pipes of the water-cooling plate 42 can be disposed in a serpentine shape, and at least part of the internal pipes can be disposed correspondingly to the first section 431 or the second cooling plate 40, so that the water-cooling plate 42 can cool the first section 431, thus improving the heat dissipation efficiency and effect of the heat pipe 43.

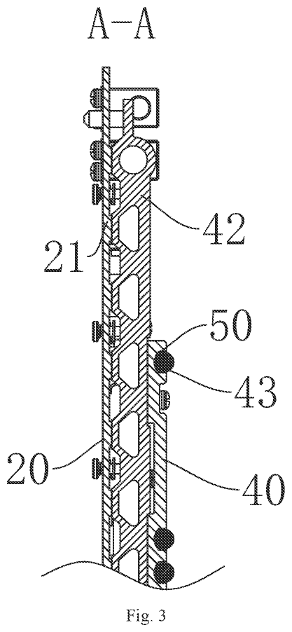

As shown in FIG. 3, the cross section of the internal pipe is an isosceles trapezoid. The two bottom edges of the trapezoid can be respectively disposed towards the Hash chip 211 and the second cooling plate 40, so that the surfaces of the internal pipe corresponding to the Hash chip 211 and the second cooling plate 40 are linear. Thus, compared with the circular, square, triangle and other cross-sections, the water-cooling plate 42 disposed in this way is convenient to reduce the distance between the internal pipe and the Hash chip 211, and the distance between the internal pipe and the first section 431, and the contact area and flow area of the trapezoidal structure are large, which is conducive to the heat dissipation of the water-cooling plate 42 at uniform temperature and reduces the flow resistance, so as to improve the heat dissipation efficiency and heat dissipation effect. In addition, the temperature of the first section 431 can be effectively reduced, thus increasing the temperature difference between the two ends of the heat pipe 43. For example, the long bottom edge of the trapezoid may be disposed towards the first section 431, so that the area of the surface of the internal pipe towards the first section 431 is larger, thus further reducing the temperature of the first section 431, and improving the heat dissipation efficiency and heat dissipation effect of the heat pipe 43 on the heat source. In addition, the thickness of the water-cooling plate 42 can be reduced. Optionally, the connection of the bottom edge and the waist line of the trapezoid can be in arc-shaped transition, thus facilitating the flow of the liquid in the internal pipe.

As shown in FIG. 9, the server 100 further comprises a baffle plate 60 and a handle 70. A plurality of baffle plates 60 are disposed at one end of the board body 21 away from the buck circuit module 22. A plurality of Hash boards 20 are disposed in the accommodation space of the housing 10. The baffle plate 60 seals the opening of the accommodation space, and the handle 70 is disposed at the side of the baffle plate 60 away from the electrical connection board. The Hash board 20 is slidably disposed in the accommodation space, and the handle 70 can be pulled or pushed to facilitate the Hash board 20 to be disposed or separated from the accommodation space.

Other components of the server 100 according to the embodiment of the disclosure, such as MOS transistors, inductance modules, and operations of the server 100, are known to ordinary skill in the art, and will not be described in detail here.

In the description of this specification, the reference to the description of the terms “one embodiment”, “some embodiments”, “schematic embodiments”, “examples”, “specific examples”, or “some examples” means that the specific features, structures, materials or features described in combination with the embodiment or examples are included in at least one embodiment or example of the disclosure. In this specification, the schematic expressions of the above terms do not necessarily refer to the same embodiments or examples.

Although the embodiments of the disclosure have been shown and described those of ordinary skill in the art can understand that a variety of changes, modifications, substitutions, and variants can be made to these embodiments without departing from the principle and purpose of the disclosure, and the scope of the disclosure is defined by the claims and their equivalents.

1. A server, comprising:
a housing in the shape of a frame structure;
a plurality of Hash boards, the plurality of Hash boards being disposed side by side in the housing along a first direction; each of the plurality of Hash boards being disposed perpendicularly to the first direction, and each Hash board comprising a board body; the board body being provided with a Hash chip; and
a cooling module configured to cool at least the plurality of Hash boards;
the cooling module comprising:
at least one first cooling plate disposed on the board body;
a water-cooling plate disposed on a side surface of the board body; and
at least one heat pipe disposed on the board body; one end of the at least one heat pipe being disposed on the at least one first cooling plate, and the other end being disposed on the water-cooling plate.

2. The server of claim 1, wherein the Hash board comprises a buck circuit module disposed on the board body and separated from the Hash chip in a second direction; the second direction is parallel to an extension direction of the Hash board, and the first cooling plate is disposed on the buck circuit module.

3. The server of claim 2, wherein a plurality of first cooling plates are disposed at intervals on the buck circuit module, and each first cooling plate corresponds to at least one heat pipe.

4. The server of claim 2, wherein the cooling module comprises one first cooling plate, and one end of each heat pipe is disposed on the one first cooling plate.

5. The server of claim 3, further comprising a second cooling plate disposed on a side surface of the water-cooling plate away from the board body, and one end of each heat pipe away from the first cooling plate is disposed on the second cooling plate.

6. The server of claim 5, wherein at least one of the first cooling plate and the second cooling plate comprise at least one elongated groove configured to accommodate a part of the heat pipe.

7. The server of claim 2, wherein a heat conducting gel configured to adjust a height of the first cooling plate is provided between the buck circuit module and the first cooling plate.

8. The server of claim 1, wherein each heat pipe comprises:
a first section disposed on one end of the water-cooling plate;
a second section disposed on one end of the first cooling plate, and a distance between the second section and the board body being less than a distance between the first section and the board body; and
a connection section disposed between the first section and the second section and presenting in a step structure.

9. The server of claim 8, wherein a relationship of a height h and a horizontal length L of the connection section is as follows: 1/20≤h/L≤½.

10. The server of claim 8, wherein the first section and the connection section, and the second section and the connection section are connected through arcs, and a radius of the arcs is greater than or equal to twice a diameter of the heat pipe.
